(19) United States
(12) Patent Application Publication
(10) Pub. No.: US 2009/0250692 A1
(43) Pub. Date: Oct. 8, 2009

(54) Radiation Detector With Asymmetric Contacts

(75) Inventors: Csaba Szeles, Allison Park, PA (US); Utpal K. Chakrabarti, Allentown, PA (US)

Correspondence Address: THE WEBB LAW FIRM, P.C., 700 KOPPERS BUILDING, 436 SEVENTH AVENUE, PITTSBURGH, PA, 15219, US

(73) Assignee: EV PRODUCTS, INC., Saxonburg, PA (US)

(21) Appl. No.: 12/419,638

(22) Filed: Apr. 7, 2009

Related U.S. Application Data
(60) Provisional application No. 61/042,834, filed on Apr. 7, 2008.

(51) Int. Cl. H01L 31/0272; H01L 21/283

(52) U.S. Cl. 257/42; 438/84; 257/E31.008; 257/E21.159

(57) ABSTRACT

A room temperature radiation detector is made from a semi-insulating Cd₁₋ₓZnₓTe crystal, where 0≦x≦1, having a first electrode made of Pt or Au on one surface of the crystal and a second electrode of Al, Ti or In on another surface of the crystal. In use of the crystal to detect radiation events, an electrical bias is applied between the first and second electrodes.

### CROSS REFERENCE TO RELATED APPLICATION

The present application claims priority to U.S. Provisional Patent Application No. 61/042,834, filed Apr. 7, 2008, entitled Radiation Detector with Asymmetric Contacts, which is incorporated herein by reference.

### BACKGROUND OF THE INVENTION

1. Field of the Invention

The present invention relates to room temperature semiconductor radiation detectors and, more particularly, to the contacts or electrodes of such room temperature semiconductor radiation detectors.

2. Description of Related Art

Semi-insulating Cd₁₋ₓZnₓTe crystals with Zn composition typically in the 0≦x≦0.25 mole fraction range are often used for room-temperature semiconductor radiation detector applications. Traditionally, Cd₁₋ₓZnₓTe crystals are outfitted with contacts of the same material (symmetrical contacts). For high resistivity but slightly n-type Cd₁₋ₓZnₓTe crystal material, high work function electrodes, typically either Pt or Au electrodes, are used to form at the cathode of the radiation detector a reverse biased Schottky barrier and at the anode of the radiation detector a forward biased Schottky diode which, in a single carrier (electron only) device, does not pose a barrier to electron flow and is typically neglected. In slightly p-type crystal material, typically low work function electrodes, such as In, Al or Ti electrodes, are used to form at the anode of the radiation detector a reverse biased Schottky barrier for hole flow at the anode and at the cathode of the radiation detector a forward biased Schottky barrier which does not represent a barrier to hole current in a single carrier (holes only) device.

### SUMMARY OF THE INVENTION

The invention is a room temperature radiation detector that includes a semi-insulating Cd₁₋ₓZnₓTe crystal, where 0≦x≦1; a first electrode made of a deposit of Pt or Au on one surface of the crystal; and a second electrode made of a deposit of Al, Ti or In on another surface of the crystal. In use of the crystal to detect radiation events, an electrical bias is applied between the first and second electrodes in such a manner that the electrode with the Pt or Au electrode is the negatively biased cathode and the electrode with the Al, Ti, or In electrode is the positively biased anode.

When the crystal is n-type, the first electrode, i.e., the negatively biased cathode, is the primary blocking electrode limiting the flow of the majority carrier electrons. When the crystal is p-type, the second electrode, i.e., the positively biased anode, is the primary blocking electrode limiting the flow of majority carrier holes.

One electrode can be segmented or pixilated.

The invention is also a method of forming a room temperature radiation detector comprising: providing a semi-insulating Cd₁₋ₓZnₓTe crystal, where 0≦x≦1; applying a first (cathode) electrode made of Pt or Au on one surface of the crystal; and applying a second (anode) electrode made of Al, Ti or In on another surface of the crystal.

The first and second electrodes can be deposited on oppositely facing surfaces of the crystal.

The crystal can be either an n-type crystal or a p-type crystal.

In response to the application of the electrical bias to the first and second electrodes, where the first electrode is at a more negative potential than the second electrode, the first electrode is operative for impeding electron flow and the second electrode is operative for impeding hole flow.

Lastly, the invention is a room temperature radiation detector comprising: a semi-insulating Cd₁₋ₓZnₓTe crystal, where 0≦x≦1; a first electrode made of a deposit of a first material on one surface of the crystal, wherein the first material has a work function value≧5.1 eV; and a second electrode made of a deposit of a second material on another surface of the crystal, wherein the first material has a work function value≦4.33 eV, wherein in response to a suitable electrical bias applied between the first and second electrodes, majority carrier flow is impeded by the first electrode and minority carrier flow is impeded by the second electrode.

The majority carriers in n-type and p-type crystals are electrons and holes, respectively.

### BRIEF DESCRIPTION OF THE DRAWING(S)

FIGS. 1 and 2 are band diagrams of a prior art semi-insulating Cd₁₋ₓZnₓTe (where 0≦x≦1) crystal with identical (symmetrical) material electrodes at the cathode (left side) and the anode (right side) before and after, respectively, the application of a bias voltage; and

FIG. 3 is a schematic diagram of a semi-insulating Cd₁₋ₓZnₓTe (where 0≦x≦1) crystal with different (asymmetrical) material electrodes at the cathode (left side) and the anode (right side).

### DETAILED DESCRIPTION OF THE INVENTION

It has been observed that semi-insulating crystals, such as high-resistivity Cd₁₋ₓZnₓTe crystals (where 0≦x≦1), are dual-carrier systems where the concentration of minority carriers is only moderately (5x to 100x) lower than the concentration of majority carriers, and both carriers contribute to current flow and dark or leakage current of radiation detector devices made from such crystals. Accordingly, the contribution of minority carriers could be significant and appropriate barrier electrodes need to be used for the anode and cathode contacts of such radiation detector devices to suppress stationary and non-stationary current contributions from the minority carriers.

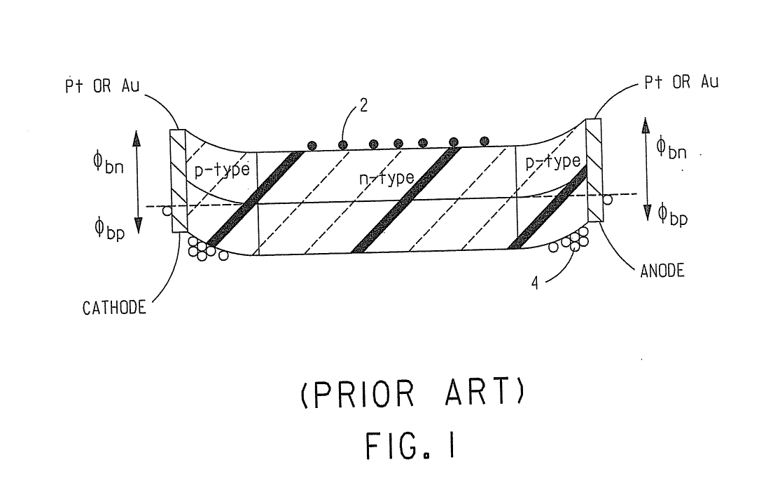

As an example, FIG. 1 shows a band diagram of a prior art slightly n-type semi-insulating Cd₁₋ₓZnₓTe (where 0≦x≦1) crystal with identical (symmetrical) material electrodes at the cathode (left side) and the anode (right side) before the application of a bias voltage. In other words, the anode and cathode electrodes are made from the same material, e.g., either Pt or Au. High work function metal electrodes (Pt or Au for semi-insulating Cd₁₋ₓZnₓTe) cause an upward bending of the band edges (shown schematically in FIG. 1) at the cathode and anode contacts of the n-type semi-insulating Cd₁₋ₓZnₓTe crystal. This results in the accumulation of holes (i.e., minority carriers in this case) beneath the contacts and this, in turn, results in the conversion of the bulk material from slightly n-type to slightly p-type in the near-contact regions. In FIG. 1, the Schottky barrier heights are denoted φ_{bn} and φ_{bp} for electrons and holes, respectively.

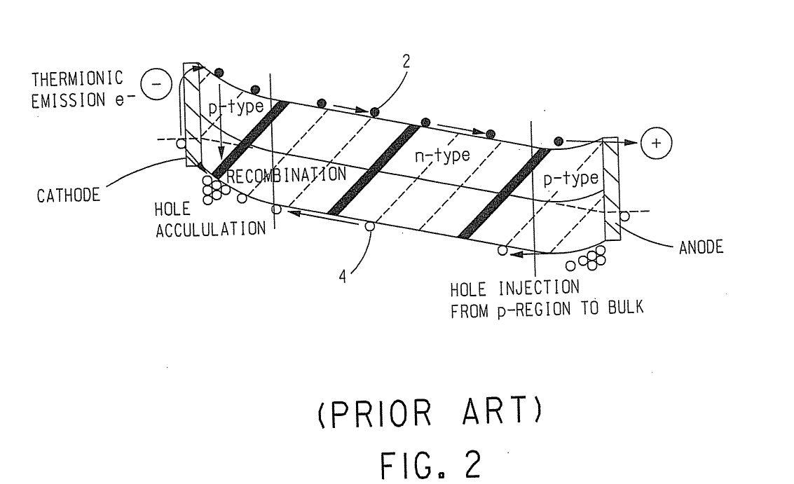

FIG. 2 shows the effect on the band diagram of FIG. 1 when a negative bias is applied to the cathode electrode (left side electrode in FIG. 2). This applied bias causes a potential drop in the bulk semiconductor material; a flow of electrons 2 (shown along the top of the n-type bulk material in FIG. 2) from the cathode electrode (left side electrode in FIG. 2) to the anode electrode (right side electrode in FIG. 2); and a reverse flow of holes 4 (shown along the bottom of the n-type bulk material in FIG. 2) from the anode electrode to the cathode electrode. The flow of majority carriers (electrons in this example) is limited by the reverse biased Schottky barrier at the cathode.

The electrons injected from the cathode electrode metal into the n-type bulk material in a thermionic emission process provide the source of electrons for the flow of electrons 2 shown along the top of the n-type bulk material in FIG. 2. Because the concentration of carriers is very low in the bulk of a semi-insulating semiconductor material, the magnitude of the majority carrier current (electrons in this example) is controlled by the injection of these carriers at the cathode contact and is determined by the height of the Schottky barrier there. The Schottky barrier to electrons at the anode disappears at very low bias (a fraction of a Volt) and essentially does not impede the flow of electrons out of the semiconductor material into the metal of the anode electrode.

The negative bias also generates a flow of holes 4 from the anode to the cathode, shown along the bottom of the n-type bulk material in FIG. 2. The source of holes is the accumulation region adjacent the anode (right side electrode in FIG. 2) and holes are injected to the bulk of the semiconductor from here. The accumulation of holes increases at the cathode (left side electrode in FIG. 2) from where they are removed by recombination with the electrons in the cathode metal. The holes 4 injected to the bulk n-type material from the accumulation region beneath the anode (right side electrode in FIG. 2) are replenished by thermal excitation (or thermionic emission) of electrons from the valence band of the n-type material to the anode metal, whereupon new holes are generated in the accumulation region of the n-type material adjacent the anode metal. This is equivalent to a process of “hole injection” from the metal to the valence band through the reverse biased hole Schottky barrier (φₚ) at the anode. Because there is no other impediment to hole flow in the system, the hole current is controlled by the hole Schottky barrier φₚ at the anode. The contribution of minority carriers (in this example holes) to charge transport in such dual-carrier system has two very significant implications to semiconductor devices fabricated using such semiconductor crystals outfitted with symmetrical contacts, i.e., contacts made from the same material.

First, minority carrier current (in this example hole current) significantly contributes to leakage and dark current of the device made with symmetrical electrical contacts. If the Schottky barrier is very large at the so-called blocking electrode for majority carriers (i.e., the cathode of an n-type semiconductor) the Schottky barrier becomes very low for the holes (note that φ_{bn}+φ_{bp}=E_{g}=constant, where E_{g} is the band gap of the semiconductor) and the minority carrier current (hole current in the present example) can exceed the majority carrier current. Under such conditions, the total leakage or dark current may exceed the useful tolerance of the device.

Second, reverse biased Schottky barriers with low barrier height, such as the anode electrode for minority holes in a slightly n-type bulk semiconductor, can go to avalanche breakdown at relatively low bias voltages. In an avalanche breakdown condition, the leakage and dark current of the device becomes excessive leading to the complete failure of the device at a lower bias voltage than the desired operating bias of the device. This leads to significant yield loss during device fabrication.

To overcome the above problems and others, asymmetric electrical contacts can be applied to the semiconductor device which establish high Schottky barrier contacts both at the anode electrode and the cathode electrode. This is achieved by fabricating the electrodes at the anode and at the cathode from dissimilar materials. The materials are specifically chosen to form a blocking contact for majority carriers at one electrode and form a blocking contact for minority carriers at the other electrode thereby forming asymmetric contacts. The used of asymmetric electrical contacts is not restricted to Schottky barrier devices or metal electrodes only, it is also applicable to other type of contacts with carrier flow and injection limiting, i.e., blocking properties.

While the principles of limiting current flow of majority carriers by blocking electrodes is widely practiced in the semiconductor industry, employing blocking electrodes for minority carriers is not known and not practiced in dual-carrier systems.

The literature is also silent regarding the principle of blocking the flow of both majority and minority carriers in room-temperature semiconductor x-ray and gamma ray detectors. In the case of semiconductor detectors fabricated from slightly n-type semi-insulating Cd₁₋ₓZnₓTe crystals with Zn composition typically in the 0≦x≦0.25 mole fraction range, electrons are the majority carriers and holes are the minority carriers. Schottky barrier electrodes using high work function metals, such as Pt (Pt work function=5.12-5.93 eV) or Au (Au work function=5.1-5.47 eV), would serve as cathode electrode for blocking the majority carrier electrons. Schottky barrier electrodes using low work function metals, such as Al (Al work function=4.06-4.26 eV), Ti (Ti work function=4.33 eV) or In (In work function=4.09 eV), would serve as the anode electrode for blocking the minority carrier holes. As used in connection with the electrodes described herein, the terms “blocking” and “block” mean fully or partially obstructing or impeding the movement of electrons or holes, as the case may be.

It is known to use Pt or Au electrodes for n-type Cd₁₋ₓZnₓTe crystals to block the flow of the majority carrier electrons and to use Al, In or Ti electrodes for p-type Cd₁₋ₓZnₓTe crystals to block the flow of majority carrier holes. What is not known, however, is (1) blocking both the majority and minority carrier flow in the same detector and (2) reducing minority carrier injection from the minority carrier blocking electrode.

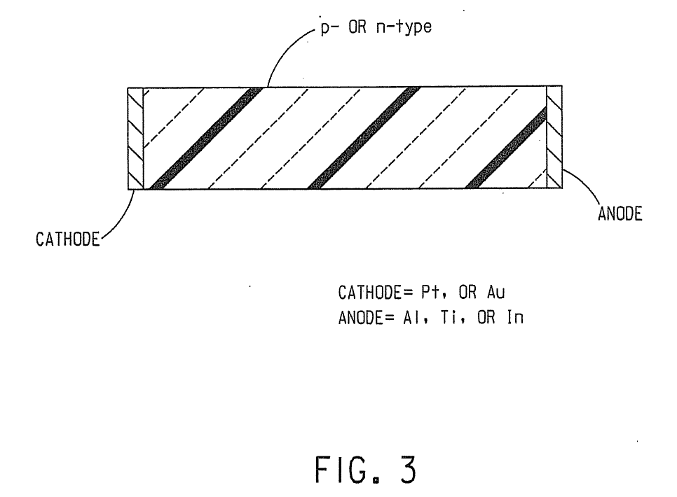

With reference to FIG. 3, one particular application to slightly n-type semiconductor is to take a semi-insulating Cd₁₋ₓZnₓTe crystal and deposit Pt or Au as the cathode Schottky barrier contact to block electron flow, and deposit Al, Ti or In as the anode Schottky barrier electrode to block hole flow through the device. Each electrode may be a full-area electrode or a segmented (e.g., pixilated) electrode.

Depositing different metals as the anode and cathode electrodes (i.e., asymmetric contacts) of a slightly n-type semiconductor, semi-insulating Cd₁₋ₓZnₓTe crystal, enables (1) blocking of both majority and minority carrier flow and (2) reduced minority carrier injection from the minority carrier blocking electrode in electrically compensated semi-insulating semiconductor detector devices.

An advantage over the prior art is improved performance of Cd₁₋ₓZnₓTe room temperature x-ray and gamma ray detectors and improved fabrication yields of these detectors. The reduced charge injection from both electrodes will reduce the leakage current of these detectors and increase breakdown voltage. This will allow operation of these detectors at higher biases that will directly convert to better spectroscopic performance, higher speed, and higher counting rate capability.

Similarly, in the case of a slightly p-type semiconductor, semi-insulating Cd₁₋ₓZnₓTe crystal, Pt and Au can be deposited as the cathode Schottky barrier contact blocking the flow of the minority carrier electrons, and Al, Ti, or In can be deposited as the anode Schottky barrier electrode to block the majority carrier hole flow through the device. Each electrode may be a full-area electrode or a segmented (e.g., pixilated) electrode.

The present invention has been described with reference to the preferred embodiments. However, this is not to be construed as limiting the invention since it is envisioned that one of ordinary skill in the art could come with obvious modifications and alterations of the preferred embodiments upon reading and understanding the preceding detailed description. It is, therefore, intended that the invention be construed as including all such modifications and alterations insofar as they come within the scope of the appended claims or the equivalents thereof.

The invention claimed is:

1. A room temperature radiation detector comprising:
a semi-insulating Cd₁₋ₓZnₓTe crystal, where 0≦x≦1;
a first electrode made of a deposit of Pt or Au on one surface of the crystal; and
a second electrode made of a deposit of Al, Ti or In on another surface of the crystal.

2. The radiation detector of claim 1, wherein the first electrode is the cathode and the second electrode is the anode.

3. The radiation detector of claim 2, wherein:
in response to the application of the electrical bias to the first and second electrodes, where the first electrode is at a more negative potential than the second electrode, the first electrode is operative for impeding electron flow and the second electrode is operative for impeding hole flow.

4. The radiation detector of claim 1, wherein one of the electrodes is segmented or pixilated.

5. A method of forming a room temperature radiation detector comprising:
providing a semi-insulating Cd₁₋ₓZnₓTe crystal, where 0≦x≦1;
applying a first electrode made of Pt or Au on one surface of the crystal; and
applying a second electrode made of Al, Ti or In on another surface of the crystal.

6. The method of claim 5, wherein the first and second electrodes are deposited on oppositely facing surfaces of the crystal.

7. The method of claim 5, wherein the crystal is either an n-type crystal or a p-type crystal.

8. The method of claim 7, wherein:
in response to the application of the electrical bias to the first and second electrodes, where the first electrode is at a more negative potential than the second electrode, the first electrode is operative for impeding electron flow and the second electrode is operative for impeding hole flow.

9. A room temperature radiation detector comprising:
a semi-insulating Cd₁₋ₓZnₓTe crystal, where 0≦x≦1;
a first electrode made of a deposit of a first material on one surface of the crystal, wherein the first material has a work function value≧5.1 eV; and
a second electrode made of a deposit of a second material on another surface of the crystal, wherein the first material has a work function value≦4.33 eV, wherein in response to a suitable electrical bias applied between the first and second electrodes, majority carrier flow is impeded by the first electrode and minority carrier flow is impeded by the second electrode.

10. The radiation detector of claim 9, wherein majority carriers in n-type and p-type crystals are electrons and holes, respectively.
